(19) United States
(12) Patent Application Publication
(10) Pub. No.: US 2011/0220864 A1
(43) Pub. Date: Sep. 15, 2011

(54) SINGLE-CRYSTALLINE GERMANIUM COBALT NANOWIRE, A GERMANIUM COBALT NANOWIRE STRUCTURE, AND A FABRICATION METHOD THEREOF

(75) Inventors: Bongsoo Kim, Daejeon (KR); Hana Yoon, Daejeon (KR)

(73) Assignee: KOREA ADVANCED INSTITUTE OF SCIENCE AND TECHNOLOGY, Daejeon (KR)

(21) Appl. No.: 13/129,292

(22) PCT Filed: Nov. 13, 2009
(86) PCT No.: PCT/KR2009/006682

§ 371 Date: May 13, 2011

(30) Foreign Application Priority Data
Nov. 14, 2008 (KR) 10-2008-0113518

(51) Int. Cl. H01L 29/66; C30B 25/00

(52) U.S. Cl. 257/10; 117/87; 257/E29.168

(57) ABSTRACT

Provided is a single-crystalline CoₓGe₁₋ₓ nanowire having x of at least 0.01 to less than 0.99, a germanium cobalt nanowire structure having a vertical alignment to the substrate and provided in the cathode of the electric field display and a method of fabricating them using the gas-phase transfer method. By providing the nanowire which uses the graphene or the highly ordered pyrolytic graphite as the substrate and has a vertical alignment to the substrate and uniform size and high density, it is possible to use the germanium cobalt nanowire as a field emission emitter and uses the substrate having the germanium cobalt nanowire formed as a cathode transparent electrode of the field emission display.

### TECHNICAL FIELD

The present invention relates to a single-crystalline CoₓGe₁₋ₓ nanowire having x of at least 0.01 to less than 0.99, a germanium cobalt nanowire structure having a vertical alignment to a substrate and provided on a cathode of an field emission display, and a fabrication method thereof using a vapor-phase transfer process.

### BACKGROUND ART

Recently, as information technology advances rapidly, it begins into a ubiquitous computing generation which can make any user access information at any place and at any time, and network, internet, digital contents, handheld information machine, multimedia and wired-wireless communication technology are combined so that it gradually becomes developed into new machine which cannot be defined according to prior concepts.

Subsequently, as an information transfer media which can easily transfer various information to any user at any place and at any time, there is an increasing need for developing a display which is easy to carry due to a super light-weight and a super slim, has a great durability and is capable of being implemented as a panel of any forms.

Particularly, as there is an increasing need for developing a display which is flexible to be fold just like a paper and is possibly even in a roll of paper, there is an increasing concern on a flexible display considered as a next generation of the flat plate display which is taking the lead in display market at present.

For the purpose of implementing the flexible display, a method of adding the flexibility by substituting partial parts of an existing liquid crystal display LCD or an organic light emitting diode OLED has been generally researched. However, it is limited to fabricate the flexible display since a liquid crystal is injected between a top plate and a bottom plate in a case of LCD. Further, there are problems related to low electroluminescence life time, large scale, and high efficiency in a case of OLED.

Meanwhile, a Field Emission Display FED has advantages of high image quality, high efficiency, and low consumption power, as well as operability in a wide range of temperature, thin productivity, low production cost, high response velocity and large scale.

Therefore, if such electric field display can be produced flexibly, it will be remarkable as a next-generation information display element. But, the research on producing the flexible field emission display remains very low level at present.

The field emission display is operated under the principle that infinite electrons are discharged from emitter to cause an image to be captured and is structured with a cathode and an anode. Basically, it is designed such that the electron discharged from the cathode is collided against a fluorescent body of the anode to cause the image to be displayed, and therefore it is operated in a manner similar to that of the existing Braun tube, as well as thin-type.

The cathode of the field emission display is structured with micro tips (Field Emitter Array) discharging the electrons and the anode of the field emission display is applied with the fluorescent body to allow the person to see the image.

Since the field emission display has many advantages such as thin type, low power consumption, low process cost, superior temperature characteristics, and high velocity operation, it may be used in a wide range of from small color TV to industrial products and computer.

A process technology for the emitter of electron discharge source and stability of the materials can be considered as the important technical elements of the field emission display. Since there is a problem of stability in cases of Si tip or Mo tip which is mainly used, it is needed to develop noble material which is easy to fabricate and is greatly stable.

A core technology of the field emission display is that the electron discharging emitter must be produced to be pointed, the characteristics must not be lowered as time passes when the voltage is applied across the produced emitter, and the emitter of stable structure can be reproduced. Further, there is a demand for a technology that can make the emitter be vertically grown or vertically raised for the purpose of high electron emission efficiency.

A carbon nanotube CNT has been remarkable as material of new field emission display up to the present time. However, since it has inherent problems of non-uniform emittance, flickering or carbon nanotube destruction, there has been a demand for new material which can remove such problems.

Further, it is important to develop a flexible substrate which may be substituted for an existing glass substrate in order to develop the flexible display, and a research of replacing the glass substrate with high molecular substrate has been mainly processed. However, since the high molecular substrate is vulnerable to heat, it is limited to produce an active matrix thin-film transistor of high performance.

Subsequently, for the purpose of producing a thin film flexible field emission display, it is necessary to develop a technology of forming the emitter on the flexible substrate which is stable and highly conductive to have a particular alignment to the substrate using new emitter material.

Meanwhile, since the graphene is very stable in conditions of heat and acid and produced in thin-film form of less than several nm, as well as has transparency and high conductivity, it can be usefully used in transparent and flexible electronic device such as electrode of the flexible field emission display or the solar cell.

The applicant initially invents a germanium cobalt single-crystalline nanowire and a germanium cobalt single-crystalline nanobelt which have superior properties of the carbon nanotube such as lower driving voltage and higher aspect ratio, as well as remove problems of the carbon nanotube due to superiority in mechanical, chemical and heat-resistance, and further invents a germanium cobalt single-crystalline nanowire structure vertically aligned on the graphene which is very stable in the conditions of heat and acid and is produced in thin-film form of less than several nm, as well as has transparency and high conductivity, which leads to an application of the invention.

The germanium cobalt nanowire Co₅Ge₇ NW is grown vertically on a highly Ordered Pyrolytic Graphite (HOPG) substrate using chemical vapor transport CVT as the flexible substrate of the field emission display, and an experiment is performed for the purpose of examining an application possibility of grown nanowire as the field emission emitter. It can be confirmed that the germanium cobalt nanowire can be grown on the HOPG substrate and the thin graphene layer, as well as grown on the graphene layer of curved type. Up to now, the flexible display technology using the high molecular substrate is actively researched, whereas the graphene layer is reported as a material of transparency, flexibility and higher conductivity at recent (G. Eda, G. Franchini, M. Chhowalla, Nature nanotech. 2008, 3, 270), which suggests an applicability as transparent conductive substrate. Further, it is expected that the germanium cobalt nanowire has the superior properties of the carbon nanotube such as lower driving voltage and larger aspect ratio, as well as removes the problems of the carbon nanotube due to superiority in mechanical, chemical and heat-resistance. Therefore, it is expected that a next-generation flexible field emission display is possibly developed via the germanium cobalt nanowire grown on the HOPG substrate.

### DISCLOSURE OF INVENTION

### Technical Problem

An embodiment of the present invention is directed to providing a single-crystalline germanium cobalt nanowire of high purity and high quality which has physical properties suitable for utilization in an emitter of a field emission display or a cathode of the field emission display, a single-crystalline germanium cobalt nanowire structure having a vertical alignment to the germanium cobalt nanobelt and a substrate, and a method of fabricating the single-crystalline germanium cobalt nanowire and the single-crystalline germanium cobalt nanowire.

### Solution to Problem

To achieve the object of the present invention, the present invention provides a single-crystalline germanium cobalt nanowire having a chemical equation 1 below.

CoₓGe₁₋ₓ (Chemical Equation 1)

(where, x is at least 0.01 to less than 0.99)

Specifically, the nanowire according to the present invention is structured with single-crystalline, and it is characterized in that the nanowire is a fully solid solution of Co and Ge or an intermetallic compound of Co and Ge

The nanowire according to the present invention is Co₅Ge₇, and at this time the nanowire has a tetragonal structure and a long axis direction of the nanowire is [100].

A turn-on electric field of the nanowire is 1.3 to 2 V/gm and a current density is at least 500 μA/cm² under the electric field of 2.5V/μm.

A ratio calculated by dividing a length of the long axis by a diameter of a short axis in the nanowire is 5 to 200.

The nanowire is an emitter of a field discharge display.

Preferably, the nanowire is generated on a substrate by heating a first precursor containing halo-cobalt at a temperature of 500° C. to 800° C., heating the substrate and a second precursor containing germanium (Ge) and carbon (C) at a temperature of 600° C. to 1000° C. and performing a heat-treatment under an environment that an inert gas of 100 to 300 sccm flows from the first precursor to the second precursor and the substrate.

A germanium cobalt nanowire structure according to other embodiment of the present invention comprises a substrate; and a single-crystalline nanowire mentioned above, wherein a long axis of the single-crystalline nanowire has a vertical alignment to a surface of the substrate.

Specifically, the single-crystalline germanium cobalt nanowire has a vertical alignment with respect to a surface of the substrate, and the vertical alignment means that a vector parallel to a long axis of the single-crystalline germanium cobalt nanowire has a vertical direction vector component.

The substrate is a flexible substrate, and preferably comprises a highly ordered pyrolytic graphite (HOPG) substrate, a graphene layer, a laminated graphene layer or a laminated substrate of them.

The substrate equipped with the germanium cobalt single-crystalline nanowire comprises a highly ordered pyrolytic graphite (HOPG) substrate, a graphene layer, a laminated graphene layer or a laminated substrate of them, and a semiconductor, a ceramic, an amorphous, a metal substrate may be equipped in a bottom part of the highly ordered pyrolytic graphite (HOPG) substrate, the graphene layer, the laminated graphene layer or the laminated substrate of them

A long axis of the single-crystalline nanowire is vertical to a surface of the substrate, that is a vector of the long axis of the single-crystalline nanowire is parallel to a vector of a direction vertical

Preferably, a ratio calculated by dividing a length of the long axis by a diameter of a short axis in the single-crystalline nanowire is 5 to 200.

The single-crystalline nanowire is an emitter of the electric emission display and the structure is provided in a cathode of the electric emission display.

The structure is fabricated such that the single-crystalline germanium cobalt nanowire having vertical alignment to the substrate is formed on the substrate by heating a first precursor containing halo-cobalt at a temperature of 500° C. to 800° C., heating a second precursor containing germanium (Ge) and carbon (C) and the substrate including a highly ordered pyrolytic graphite (HOPG) substrate, a graphene layer, a laminated graphene layer or a laminated substrate of them at a temperature of 600° C. to 1000° C. and performing a heat-treatment under an environment that an inert gas flows from the first precursor to the second precursor and the substrate.

A fabrication method of the germanium cobalt single-crystalline nanowire according to the present invention is characterized in that a heat-treatment on a first precursor containing halo-cobalt located on a upstream zone of a furnace, a second precursor containing germanium (Ge) located on a downstream zone of the furnace, and a substrate located on the downstream zone of the furnace are performed in an inert gas environment so that a single-crystalline CoₓGe₁₋ₓ nanowire having x of at least 0.01 to less than 0.99 is formed on the substrate.

Preferably, the second precursor further contains carbon, and a ratio of germanium to cobalt composing the germanium cobalt single-crystalline nanowire is controlled by controlling a mixing ratio of germanium to carbon contained in the second precursor.

The precursors are powder-type, and the second precursor is a mixing powder-type of powders different from each other if the second precursor further contains carbon

Preferably, a mass ratio of germanium to carbon contained in the second precursor is 10:1 to 1:20, and therefore the single-crystalline CoₓGe₁₋ₓ nanowire having x of at least 0.01 to less than 0.99 is selectively formed.

Preferably, a mass ratio of germanium to carbon contained in the second precursor is 0.8:1 to 1:0.8 and the nanowire is Co₅Ge₇.

The first precursor is halo-cobalt in a chemical equation 2 below.

CoYₙ (Chemical Equation 2)

(where, Y is halogen element selected from F, Cl, Br or I, and n is 2 or 3)

The first precursor is equipped in an upstream zone of the furnace, the substrate and the second precursor is equipped in a downstream zone of the furnace, and the second precursor is located in a bottom part of the substrate. Preferably, the substrate is located on the second precursor put in an alumina pot of high purity.

The substrate comprises a highly ordered pyrolytic graphite (HOPG) substrate, a graphene layer, a laminated graphene layer or a laminated substrate of them, and a semiconductor, a ceramic, an amorphous, a metal substrate may be equipped in a bottom part of the highly ordered pyrolytic graphite (HOPG) substrate, the graphene layer, the laminated graphene layer or the laminated substrate of them

The nanowire has a vertical alignment to a surface of the substrate, and preferably a long axis of the nanowire is vertical to a surface of the substrate.

The upstream zone (first precursor) of the furnace is maintained at a temperature of 500° C. to 800° C. and the downstream zone (second precursor and substrate) of the furnace is maintained at a temperature of 600° C. to 1000° C. At this time, the inert gas flows from the upstream zone to the downstream zone in the furnace and a flow rate of the inert gas is 100 to 300 sccm.

The fabrication method of the germanium cobalt single-crystalline nanowire according to other aspect of the present invention is characterized in that a heat-treatment on a first precursor containing halo-cobalt located on a upstream zone of a furnace, a second precursor containing germanium (Ge) located on a downstream zone of the furnace, and a substrate including a highly ordered pyrolytic graphite, a graphene layer, an laminated graphene layers, or an laminated substrate of them located on the downstream zone of the furnace are performed in an inert gas environment so that a single-crystalline CoₓGe₁₋ₓ nanowire having x of at least 0.01 to less than 0.99 is formed with a vertical alignment to the substrate.

Preferably, the second precursor further contains carbon, and a ratio of germanium to cobalt composing the germanium cobalt single-crystalline nanowire is controlled by controlling a mixing ratio of germanium to carbon contained in the second precursor.

The precursors are powder-type, and the second precursor is a mixing powder-type of powders different from each other if the second precursor further contains carbon.

Preferably, a mass ratio of germanium to carbon contained in the second precursor is 10:1 to 1:20, and therefore the single-crystalline CoₓGe₁₋ₓ nanowire having x of at least 0.01 to less than 0.99 is selectively formed.

Preferably, a mass ratio of germanium to carbon contained in the second precursor is 0.8:1 to 1:0.8 and the nanowire is Co₅Ge₇.

The first precursor is halo-cobalt in a chemical equation 2 below.

CoYₙ (Chemical Equation 2)

(where, Y is halogen element selected from F, Cl, Br or I, and n is 2 or 3)

The first precursor is equipped in aan upstream zone of the furnace, the substrate and the second precursor is equipped in a downstream zone of the furnace, and the second precursor is located in a bottom part of the substrate. Preferably, the substrate is located on the second precursor put in an alumina pot of high purity.

Preferably a long axis of the nanowire is vertical to a surface of the substrate.

The upstream zone (first precursor) of the furnace is maintained at a temperature of 500° C. to 800° C. and the downstream zone (second precursor and substrate) of the furnace is maintained at a temperature of 600° C. to 1000° C. At this time, the inert gas flows from the upstream zone to the downstream zone in the furnace and a flow rate of the inert gas is 100 to 300 sccm.

### Advantageous Effects of Invention

The germanium cobalt nanowire according to the present invention has advantages of high pure and high quality single-crystalline, high aspect, mechanical, chemical and heat-resistance, low turn-on electric field, and high current density. Further, the nanowire structure according to the present invention has advantages in that it is very stable in conditions of heat and acid, as well as has a vertical alignment to the substrate on the substrate which can be produced in super-slim type, it is very transparent and conductive, and is equipped with the germanium cobalt nanowires of high density which are physically separated to one another and has uniform size, and the vertical alignment is maintained on the local surface equipped with the nanowire even when the substrate is not flat but curved.

The fabrication method of the germanium cobalt nanowire or the nanowire structure has advantages in that the fabrication method is simple as a vapor-phase transport process without using catalyst, any nano body rather than the germanium cobalt nanowire is not fabricated, as well as it is possible to obtain the germanium cobalt nanowire which is pure and uniform, fabricate the nanowire of high quality which is not mixed with impurities, and fabricate the germanium cobalt nanowire which has a vertical alignment to the substrate.

Further, the present invention provides the germanium cobalt nanowire structure which uses the graphene or highly ordered pyrolytic graphite as a substrate and has a vertical alignment to the substrate and uniform size, so that the germanium cobalt nanowire according to the present invention may be used as field emission emitter and the substrate having the germanium cobalt nanowire formed may be used as the cathode transparent electrode of the field emission display.

### BRIEF DESCRIPTION OF DRAWINGS

FIG. 1 is a drawing showing a fabrication method according to present invention.

FIG. 2 is a scanning electron microscope photograph of the germanium cobalt nanowire vertically grown on the highly ordered pyrolytic graphite (HOPG) substrate, in which FIG. 2(a) is a low-magnification scanning electron microscope photograph observed by tilting the germanium cobalt nanowire vertically grown on the HOPG substrate at 45 degree and FIG. 2(b) is a high-magnification scanning electron microscope photograph, and at this time the photograph inserted into FIG. 2(b) is a nanowire tip photograph observed from top-view (a scale-bar is 200 nm).a scanning electron microscope photograph of a germanium cobalt nanowire which is vertically grown on a highly ordered pyrolytic graphite (HOPG) substrate.

FIG. 3 is a scanning electron microscope photograph of a cross-section of the germanium cobalt nanowire vertically grown composed on the graphene layers.

FIG. 4 is a scanning electron microscope photograph of a cross-section of the germanium cobalt nanowire composed on the graphene layers curved.

FIG. 5 is a transmission electron microscope TEM photograph of the germanium cobalt nanowire vertically grown on the highly ordered pyrolytic graphite (HOPG) substrate, in which FIG. 5(a) is a transmission electron microscope photograph of the germanium cobalt nanowire vertically grown on the HOPG substrate and at this time a photograph inserted into FIG. 5(a) is a selected area electron diffraction SAED pattern of the germanium cobalt nanowire, and FIG. 5(b) is a High Resolution Transmission Electron Microscope HRTEM photograph and at this time a photograph inserted into FIG. 5(b) is two-dimensional Fast Fourier Transform FFT pattern.a transmission electron microscope photograph of the germanium cobalt nanowire vertically grown on the highly ordered pyrolytic graphite (HOPG) substrate.

FIG. 6 is a drawing showing a result of an energy dispersion analysis (TEM-EDS) of the germanium cobalt nanowire vertically grown on the highly ordered pyrolytic graphite (HOPG) substrate.

FIG. 7 is a scanning electron microscope photograph of the germanium cobalt nanobelt vertically grown on the highly ordered pyrolytic graphite (HOPG) substrate, in which FIG. 7(a) is a low-magnification scanning electron microscope photograph observed by tilting the germanium cobalt nanobelt vertically grown on the HOPG substrate at 45 degree and FIG. 7(b) is a high-magnification scanning electron microscope photograph, and at this time the photograph inserted into FIG. 7(b) is a nanobelt tip photograph observed from top-view (a scale-bar is 200 nm).

FIG. 8 is a transmission electron microscope TEM photograph of the germanium cobalt nanobelt vertically grown on the highly ordered pyrolytic graphite (HOPG) substrate, in which FIG. 8(a) is a transmission electron microscope photograph of the germanium cobalt nanobelt vertically grown on the HOPG substrate and at this time a photograph inserted into FIG. 8(a) is a selected area electron diffraction SAED pattern of the germanium cobalt nanobelt, and FIG. 8(b) is a High Resolution Transmission Electron Microscope HRTEM photograph and at this time a photograph inserted into FIG. 8(b) is two-dimensional Fast Fourier Transform FFT pattern.

FIG. 9 is a drawing showing a current density according to electric field of the germanium cobalt nanowire vertically grown on the highly ordered pyrolytic graphite (HOPG) substrate, in which circles and black squares represent a field emission characteristic according to germanium cobalt nanowire produced and black triangles represent a characteristic of only HOPG substrate without the nanowire.

### BEST MODE FOR CARRYING OUT THE INVENTION

The nanowire, the nanostructure and the fabrication method of the invention will be specifically described with reference to the accompanying drawings, which is set forth hereinafter. The accompanying drawings are provided as examples in order to allow a scope of the present invention to be sufficiently delivered to the skilled man to the related art. Therefore, the present invention is not limited to drawings which is set forth hereinafter but can be embodied as other aspects. Further, it is noted that like components or parts represent possibly like reference numerals through the specification.

At this time, the technical terms and science terms used in the specification have meanings which can be understood by the man skilled in the art to which the present invention belongs, and the specific explanations on known function or structure are omitted which unnecessarily can make the subject matter of the present invention obvious.

A fabrication method of a germanium cobalt single-crystalline nanowire according to the present invention is characterized in that a heat-treatment on a first precursor located on a upstream zone of a furnace, a second precursor located on a downstream zone of the furnace, and a substrate located on the downstream zone of the furnace are performed in an inert gas environment so that a single-crystalline germanium cobalt nanowire may be formed on a surface of the substrate.

The fabrication method can control a temperature of the upstream zone (first precursor) of the furnace and a flow rate of the inert gas to control an amount of the first precursor supplied to the substrate, and control a temperature of the downstream zone (substrate and second precursor) of the furnace to control an amount of the second precursor supplied to the substrate and nucleation and growth rates of the germanium cobalt material in the substrate.

Therefore, since the method can control each temperature of the upstream zone and the downstream zone of the furnace and control the flow rate of the inert gas and a pressure in the heat-treatment tube used upon heat-treatment as necessary, and ultimately control a nucleation driving force, a growth driving force, the nucleation and growth rates of the germanium cobalt material in a top portion of the substrate, a size of the germanium cobalt single-crystalline nanowire and a density on the substrate can be controlled and the germanium cobalt single-crystalline nanowire of high quality which can be reproduced and have no defect and good crystallinity can be fabricated.

The first precursor is preferably a cobalt precursor among a germanium precursor and a cobalt precursor, and the second precursor is preferably a germanium precursor.

The cobalt precursor is preferably halo-cobalt and the halo-cobalt is a cobalt fluoride, a cobalt chloride, a cobalt bromide or a cobalt iodide and more preferably the cobalt chloride. At this time, the halo-cobalt includes an anhydrous halo-cobalt, and the cobalt fluoride includes an anhydrous cobalt fluoride, the cobalt chloride includes an anhydrous cobalt chloride, the cobalt bromide includes an anhydrous cobalt bromide, and the cobalt iodide includes an anhydrous cobalt iodide.

The germanium precursor is preferably a germanium.

Preferably, the second precursor further contains C in order to control an amount of second precursor supplied to the substrate independently from the temperature of the downstream zone of the furnace.

Preferably, the second precursor contains a mixing powder of germanium powder and carbon powder to cause the carbon to control the gasification level of the germanium, so that the amount of the germanium (vapor phase) supplied to the substrate may be controlled independently from the temperature in the downstream zone of the furnace.

The substrate located in the downstream zone of the furnace together with the second precursor can be located so that the inert gas may flow from the second precursor to the substrate and located on an upper part of the second precursor.

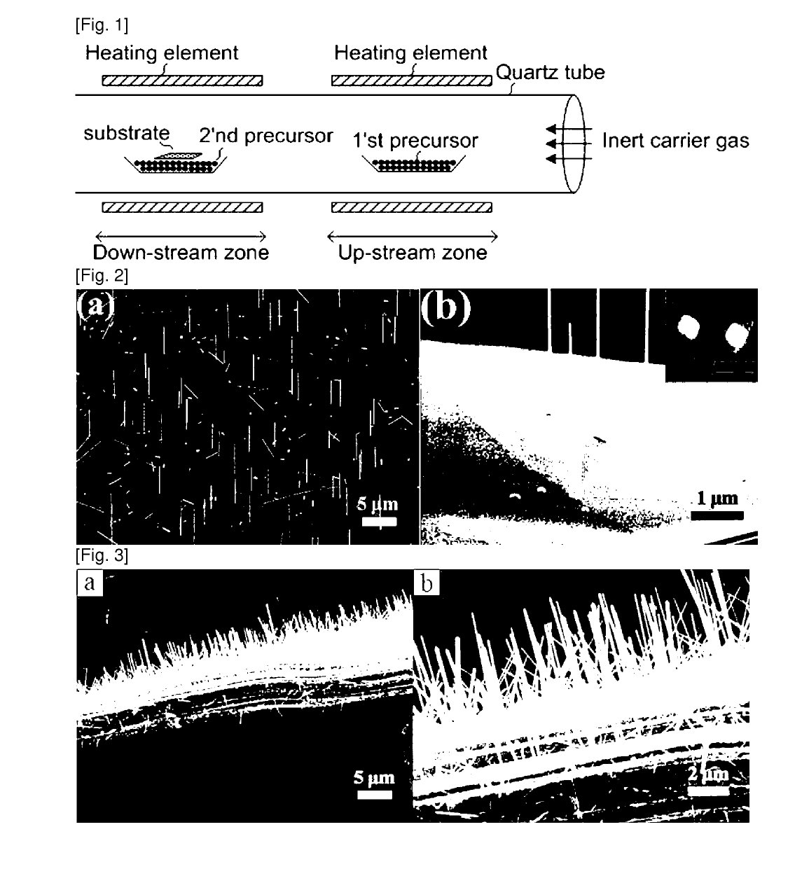

As shown in FIG. 1, the substrate is preferably located on the upper part of the second precursor to cause a very small amount of vapor-phase germanium to be supplied uniformly.

The substrate may be a stable single-crystalline/poly-crystalline conductor, semi-conductor, and nonconductor which are chemical/heat-stable upon heat-treatment, and more preferably single-crystalline substrate of possibly low tension due to lattice mismatch with germanium cobalt in order to fabricate the germanium cobalt nanowire having a particular alignment to the substrate. The substrate may comprise a highly ordered pyrolytic graphite (HOPG) substrate, a graphene layer, a laminated graphene layer or a laminated substrate of them so that the germanium cobalt nanowire may have a vertical alignment to the substrate and be provided in the cathode of the flexible display.

As a material showing transparent, flexible and conductive properties, a research on the graphene layer has been reported (G. Eda, G. Fanchini, M. Chhowalla, Nature nanotech. 2008, 3, 270).

This suggests the applicability of the graphene, the highly ordered pyrolytic graphite or the laminated substrate of them as the transparent conductive substrate. The present invention provides the germanium cobalt nanowire structure which uses the graphene or the highly ordered pyrolytic graphite as the substrate and has a vertical alignment to the substrate and uniform size and high density, and the fabrication method of the nanostructure which uses the germanium cobalt nanowire according to the present invention as field emission emitter and uses the substrate having the germanium cobalt nanowire formed as the cathode transparent electrode of the field emission display.

Due to epitaxial relation between the highly ordered pyrolytic graphite (HOPG) substrate, the graphene layer, the laminated graphene layer or the laminated substrate of them and the germanium cobalt nanowire, several germanium cobalt nanowires formed on the substrate has a parallel relation to one another other, and the germanium cobalt nanowire has the particular vertical alignment to the substrate.

As described above, the fabrication method according to the present invention is characterized in that the germanium cobalt nanowire is fabricated via gas-phase transfer method using halo-cobalt and germanium as precursor. As major conditions upon heat-treatment for the purpose of fabricating the nanowire of high quality, high purity, desirable shape, and particular composition, there are each temperature at the upstream zone and the downstream zone of the furnace, the flow rate of the inert gas, a pressure upon the heat-treatment, and the mixing ratio of germanium and carbon.

The each temperature at the upstream zone (first precursor) and the downstream zone (second precursor) of the furnace must be controlled considering physical properties such as a melting point, an evaporation point, and an evaporation energy, the flow rate of the inert gas, and the pressure upon the heat-treatment. The temperature at the upstream zone (first precursor) of the furnace is 500° C. to 800° C. and the temperature at the downstream zone (second precursor) of the furnace is 600° C. to 1000° C.

The inert gas of 100 to 300 sccm flows from the upstream zone (first precursor) to the downstream zone (second precursor) in the furnace.

The pressure upon the heat-treatment is preferably in a pressure range similar to a normal pressure (0.9˜1.1 atm) and more preferably the normal pressure (1 atm).

A mass ratio of germanium to carbon contained in the second precursor is 10:1 to 1:20, and the composition of the germanium cobalt nanowire is controlled by controlling the mass ratio of the germanium to carbon under the above-mentioned conditions of the upstream zone of the furnace, the downstream zone of the furnace, the flow rate of the inert gas and the pressure. Specifically, it is possible to fabricate Co-rich germanium cobalt nanowire by increasing an amount of carbon based on the amount of germanium and fabricate Ge-rich germanium cobalt nanowire by reducing an amount of carbon.

The mass ratio of germanium to carbon contained in the second precursor is controlled to be 10:1 to 1:20 and therefore single-crystalline CoₓGe₁₋ₓ nanowire having x of at least 0.01 to less than 0.99 is selectively fabricated. At this time, if the carbon is contained less than 0.1 weight part based on a mass of germanium, its content is insignificant, which results in fabricating the germanium cobalt nanowire having composition similar to that of the second precursor not containing the carbon.

An intermetallic compound Co₅Ge₇ nanowire is fabricated by controlling the mass ratio of germanium to carbon contained in the second precursor to be 0.8:1 to 1:0.8.

The temperature condition of the furnace, the flow rate condition of the inert gas, the pressure condition upon the heat-treatment, the mixing ratio of the carbon can influence an evaporation level of each precursor, an amount of precursor transferred to the substrate per a time, nucleation and growth rates of germanium cobalt material on the substrate, a long/short axis length ratio of nanowire for heat-treatment time, a surface energy of germanium cobalt material (nanowire) generated on the substrate, a cohesion rate of germanium cobalt material (nanowire) generated on the substrate, a morphology of germanium cobalt material (nanowire) generated on the substrate.

Subsequently, it is possible to fabricate a ferromagnetism metal nanowire of most preferable quality and shape via the evaporation transfer method using the precursor according to the present invention under the conditions of the temperature, the flow rate of the inert gas and the pressure upon the heat-treatment. If it is out of the conditions, there can be a problem of quality such as cohesion, shape change and defect of the fabricated nanowire and a problem of obtaining a metal body of such as particle and rod, not a shape of nanowire.

Since the heat-treatment time influence a density of nanowire, a long/short axis ratio and a length of nanowire, it must be properly controlled according to usage of the germanium cobalt nanowire and is preferably 2 minutes to 1 hour.

The germanium cobalt nanowire fabricated according to the present invention is characterized in that the long/short ratio calculated by dividing a length of the long axis by a diameter of the short axis is 5 to 200.

The precursors evaporated for the heat-treatment time are moved to the substrate and therefore participated into nucleation and growth, and at the same time movement of materials of an atom or cluster unit occurs through gas phase and substrate surface among germanium cobalt materials already formed on the substrate.

Therefore, it is needless to say that the density, size and the like of the germanium cobalt nanowire can be controlled by heat-treating the substrate on which the germanium cobalt nanowire is formed again in a temperature range that the material can move at the state that the precursor is removed after the heat-treatment.

A turn-on electric field of the germanium cobalt nanowire according to the present invention is 1.3 to 2 V/μm and the current density is at least 500 μA/cm² under the electric field of 2.5V/μm.

It will be appreciated that the germanium cobalt nanowire can satisfy the electric characteristics required for the emitter of the field emission display, and further the germanium cobalt nanowire is epitaxially grown with the vertical alignment on a upper part of the highly ordered pyrolytic graphite (HOPG) substrate or the graphene, has the size and the long/short axis ratio of each germanium cobalt nanowire uniform and maintains the vertical alignment (vertical alignment to local surface on which the nanowire is formed) even on a curved substrate, and therefore can be efficiently utilized for the cathode of the field emission display.

### EMBODIMENT

The embodiment uses an apparatus and a structure similar to those of FIG. 1, in which the furnace is divided into the upstream zone and the downstream zone, which are provided with a heating body and a temperature control device independently.

The furnace is consisted of a quartz tube, in which a boat-type vehicle of alumina material for inputting the first precursor is located in a middle of the upstream zone of the furnace, and a boat-type vehicle of alumina material for inputting the second precursor is located in a middle of the downstream zone of the furnace.

Argon is used as the inert gas, and the Argon gas is injected into the upstream zone of the furnace and discharged to the downstream zone in the furnace, and a vacuum pump (not shown) is provided in the downstream zone of the furnace.

The furnace is used with that of quartz material having a diameter of 1 inch and a length of 60 cm.

Anhydrous cobalt chloride (II) is used as the first precursor and a mixing powder of germanium powder and carbon powder in a mass ratio of 1:1 is used as the second precursor.

The mixing powder is fully filled within the boat-type vehicle (length 70 mm, width 15 mm, height 10 mm), the highly ordered pyrolytic graphite (HOPG) substrate (5 mm×5 mm) is located above it and then they are located in the middle of downstream zone of the furnace.

The anhydrous cobalt chloride (II) of 0.03 g is inputted into the boat-type vehicle (length 60 mm, width 8 mm, height 7 mm) and then they are located in the middle of the upstream zone of the furnace.

After it is confirmed that there is no leakage inside the furnace after performing a vacuum test of the furnace using the vacuum pump, the inside of the furnace is controlled at a normal pressure and Ar of 200 sccm is injected inside the furnace of normal pressure to allow Ar to flow from the upstream zone to the downstream zone in the furnace.

The heat-treatment is performed for about 10 minutes at the state that the temperature of the upstream zone of the furnace is maintained at 650° C. and the temperature of the downstream zone of the furnace is maintained at 900° C.

The germanium cobalt nanowire is composed in the upstream zone of the graphene substrate in the conditions similar to those of the above-mentioned embodiment after substituting only highly ordered pyrolytic graphite substrate for the laminated graphene.

FIG. 2 is a scanning electron microscope photograph observed by tilting the germanium cobalt nanowire grown on the highly ordered pyrolytic graphite (HOPG) substrate at 45 degree, in which FIG. 2(a) is a low-magnification photograph and FIG. 2(b) is a high-magnification photograph, and at this time the photograph inserted into a right top part of FIG. 2(b) is a nanowire tip photograph observed from top-view (a scale-bar of the inserted drawing of FIG. 2(b) is 200 nm).

It will be appreciated that the nanowires of high density are of an uniform size and are grown vertically to the substrate from FIG. 2 and the nanowire has quadrilateral cross-section from the scanning microscope photograph taken from top-view of FIG. 2(b).

It will be appreciated that the short axis diameter of the nanowire fabricated in FIG. 2 is 100-200 nm on an average, the length of most nanowires is at least several micrometer, and the long/short axis ratio of the nanowire is 5 to 200.

FIG. 3 is a scanning electron microscope photograph of a cross-section of the germanium cobalt nanowire composed on the graphene layers. It can be confirmed that the germanium cobalt nanowire is vertically grown on the graphene layer from FIG. 3.

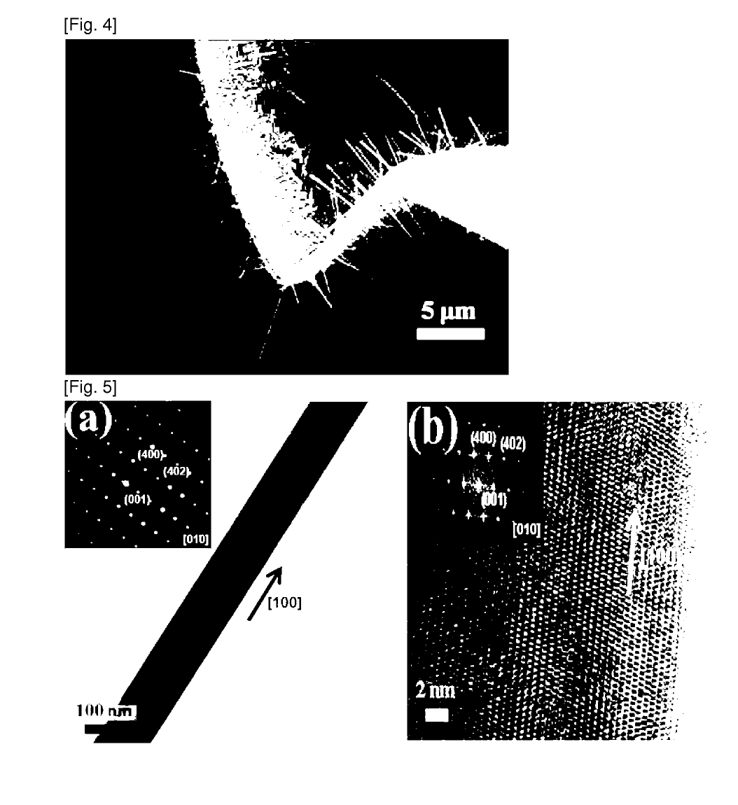

FIG. 4 is a scanning electron microscope photograph of the germanium cobalt nanowire vertically grown on curved graphene layers. It will be appreciated that the germanium cobalt nanowire is epitaxially grown even at the state that the graphene layer is curved and bent and the vertical alignment to a local surface of the graphene having the nanowire formed is maintained without a relation to whole curve.

FIG. 5 is a transmission electron microscope TEM photograph of the germanium cobalt nanowire vertically grown on the highly ordered pyrolytic graphite (HOPG) substrate, in which FIG. 5(a) is a dark filed image of the fabricated nanowire and at this time a pattern inserted into left top part of FIG. 5(a) is a selected area electron diffraction SAED pattern of the nanowire observed in FIG. 5(a), and FIG. 5(b) is High Resolution Transmission Electron Microscope HRTEM photograph and at this time a pattern inserted into left top part of FIG. 5(b) is two-dimensional Fast Fourier Transform FFT pattern of the nanowire observed in FIG. 5(b).

The singular nanowire having smooth surface and uniform thickness is composed of single-crystalline, as noted from FIG. 5(a). Further, the nanowire has a high crystallization and is single-crystalline of high quality having nearly no line defect and surface defect, as noted from FIG. 5(b).

As a result of analyzing the patterns of FIGS. 5(a) and 5(b), it is appreciated that the germanium cobalt single-crystalline fabricated is a tetragonal structure and Co₅Ge₇ of tetragonal structure (Space group I4 mm, reference: JCPDS card No. 30-0435).

Further, it is appreciated that a growth direction (long axis direction) of the germanium cobalt nanowire is [100] direction via indexing of the pattern.

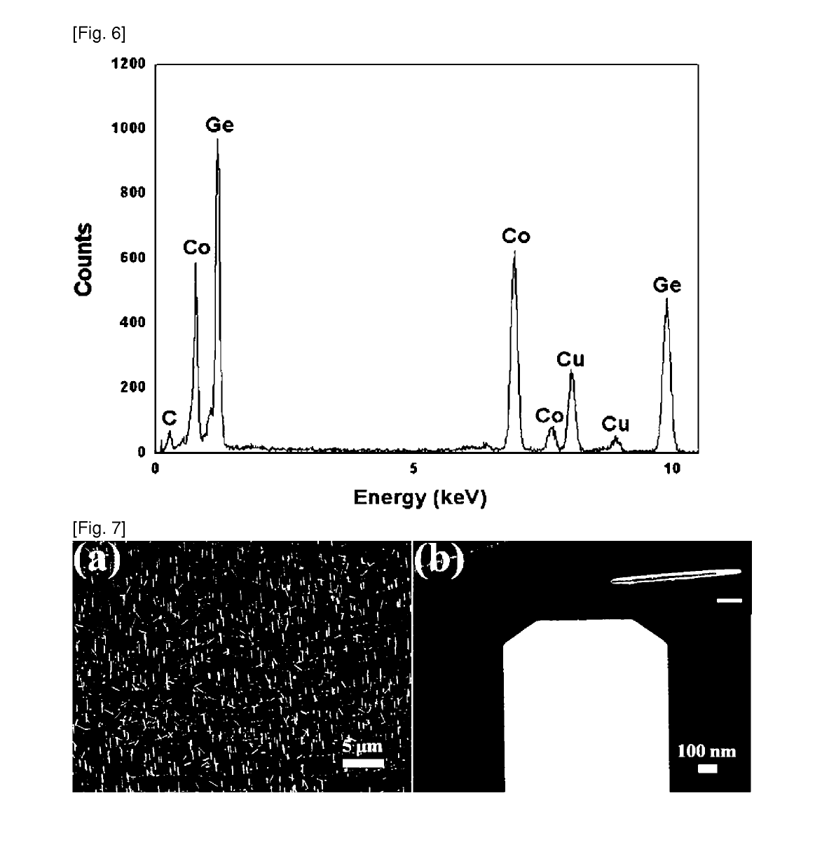

FIG. 6 is a drawing showing a result of analyzing a composition of the nanowire using an energy dispersion analyzer (TEM-EDS) attached to the transmission electron microscope. It will be appreciated that the nanowire fabricated is composed of cobalt and germanium in a ratio of 5:7 from FIG. 6. At this time, a component of Cu and C is a component of TEM grid.

TEM-EDS analysis is performed for many zones of a plurality of nanowires or single nanowire. As a result of it, it is confirmed that only Co₅Ge₇ nanowire is fabricated and single nanowire is homogeneously composed of Co₅Ge₇.

FIG. 7 is a scanning electron microscope photograph of the germanium cobalt nanobelt fabricated using a method similar to the fabrication method of the germanium cobalt nanowire according to the present invention, in which the germanium cobalt nanobelt is vertically grown on the substrate with making a flow of a carrier gas lower under the temperature condition of a first precursor, a second precursor, substrate, a upstream zone of a furnace and a downstream zone of the furnace that are similar to the fabrication method of the germanium cobalt nanowire according to the present invention.

FIG. 7(a) and FIG. 7(b) are scanning electron microscope photographs observed by tilting the fabricated germanium cobalt nanobelt at 45 degree. It is appreciated that the nanobelt has a truncated rectangular shape from FIG. 7(b) and the nanobelt has a rectangular section from an inserted photograph of FIG. 7(b) taken from top-view.

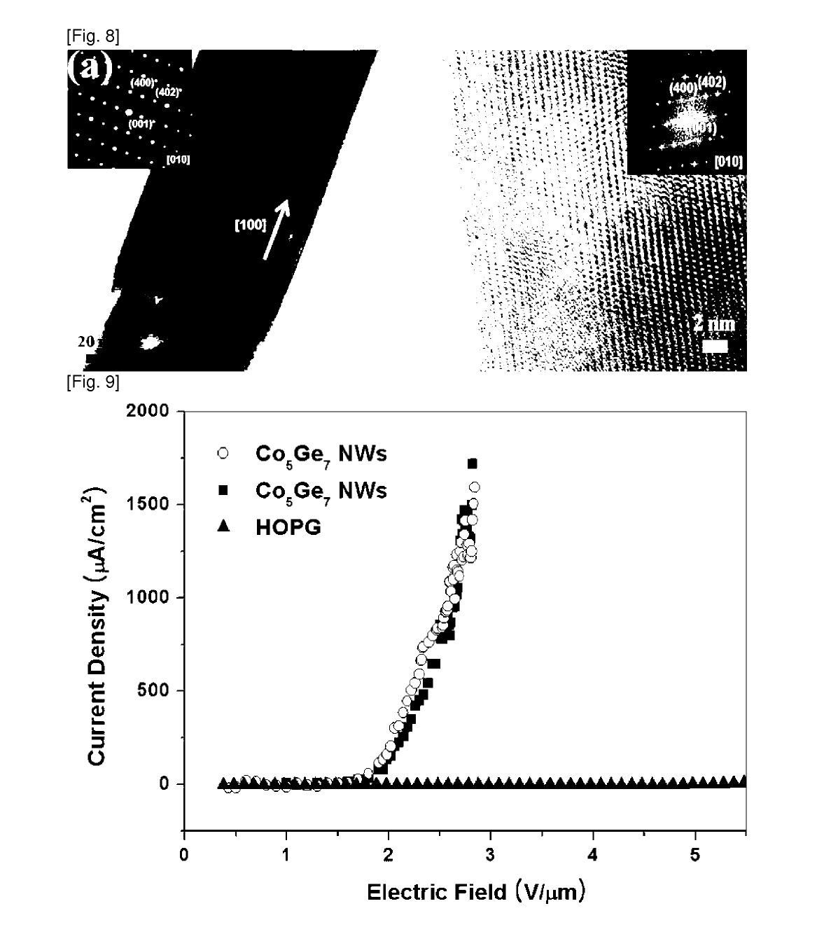

FIG. 8(a) is a transmission electron microscope TEM photograph of the germanium cobalt nanobelt fabricated, and an inserted photograph of FIG. 8(a) is a selected area electron diffraction SAED pattern of the germanium cobalt nanobelt. It represents that the diffraction pattern for the fabricated nanobelt is also a typical point pattern, which proves that the nanobelt has single-crystalline.

As a result of performing the structure analysis of the nanobelt composed via the diffraction pattern, it can be confirmed that the nanobelt conforms to tetragonal Co₅Ge₇ similarly to the nanowire (Space group 14 mm, reference: JCPDS card No. 30-0435).

FIG. 8(b) is a High Resolution Transmission Electron Microscope HRTEM photograph of the nanobelt, and an inserted photograph of FIG. 8(b) is two-dimensional Fast Fourier Transform FFT pattern obtained through the high resolution transmission electron microscope photograph. As a result of FFT pattern analysis, it can be confirmed that the composed nanobelt is single-crystalline Co₅Ge₇ having tetragonal structure and has a growth direction [100].

Further, TEM-EDS analysis is performed for many areas of the nanobelt, and as a result of it, it can be confirmed that the cobalt and germanium exist in a ratio of 5:7 over whole area similarly to case of the nanowire.

As a result of observing multiple nanobelts via the scanning electron microscope and the transmission electron microscope, it is confirmed that the nanobelt having the width of 100 nm to 1 μm, thickness of 30 to 45 nm, length of several micrometer is fabricated.

FIG. 7 and FIG. 8 are provided as examples that the germanium cobalt nanowire having regular shape and high aspect ratio can be fabricated via the vapor-phase transfer process, as well as one dimensional nanostructure such as single-crystalline germanium cobalt nanobelt and single-crystalline germanium cobalt nanorod can be fabricated by controlling the temperature of the upstream zone of the furnace, the temperature of the downstream zone of the furnace, or flow rate of the carrier gas. Therefore, the fabrication method according to the present invention can not be limited only to the fabrication method of the nanowire.

Hereinafter, it will be described on electric characteristics of the germanium cobalt nanowire structure vertically grown on the graphene or the HOPG substrate.

For the purpose of measuring the electric characteristics of the fabricated nanowire and the nanowire vertically grown on and graphene or HOPG substrate, two plates of a cathode and an anode are supplied within the vacuum chamber. As the cathode is used the HOPG substrate on which the germanium cobalt nanowire (Co₅Ge₇ nanowire) is vertically grown and as the anode is used Cu plate. The experiment for estimating field emission characteristics is performed within a chamber that is under the vacuum of 2×10⁻⁶ Torr at a normal temperature. The distance between the anode and the germanium cobalt nanowire (emitter tip) is 500 μm and the measuring area is 25 mm².

FIG. 9 is a current density graph according to electric field of the germanium cobalt nanowire vertically grown on the highly ordered pyrolytic graphite (HOPG) substrate. A J (current density)−E (electric field) characteristic is measured as the voltage of 100 to 1500V is applied in the vacuum chamber of 2×10⁻⁶ Torr. In FIG. 9, the graph indicates a field emission characteristic of the grown germanium cobalt nanowire and a field emission characteristic of only HOPG substrate without the nanowire is also measured as experimental group.

It is noted that the turn-on electric field of the grown nanowire is 1.67V/μm and at this time the current density is 102.9 μA/cm². And, a threshold electric field is 2.8V/μm and at this time the current density is 1.7 mA/cm².

It is confirmed that the electric field emission characteristic of the nanowire can be reproduced and the electric field emission characteristic of only HOPG substrate which is measured as the experimental group can not be reproduced, via several measurements.

The electric field discharge characteristic value mentioned-above suggests that the germanium cobalt nanowire can be used as a field discharge emitter and the substrate having the nanowire such as HOPG and graphene vertically grown is used as the cathode electrode of the field emission display.

While the present invention has been described with respect to the specific embodiments, it will be apparent to those skilled in the art that various changes and modifications may be made without departing from the spirit and scope of the invention as defined in the following claims.

1. A single-crystalline germanium cobalt nanowire having a chemical equation 1 below.
CoₓGe₁₋ₓ (Chemical Equation 1)
(where, x is at least 0.01 to less than 0.99)

2. The single-crystalline germanium cobalt nanowire of claim 1, wherein the nanowire is Co₅Ge₇.

3. The single-crystalline germanium cobalt nanowire of claim 2, wherein the nanowire has a tetragonal structure and a long axis direction of the nanowire is [100].

4. (canceled)

5. The single-crystalline germanium cobalt nanowire of claim 2, wherein a turn-on electric field of the nanowire is 1.3 to 2 V/μm.

6. The single-crystalline germanium cobalt nanowire of claim 1, wherein a ratio calculated by dividing a length of the long axis by a diameter of a short axis in the nanowire is 5 to 200.

7. The single-crystalline germanium cobalt nanowire of claim 1, wherein the nanowire is an emitter of a field discharge display.

8. (canceled)

9. A germanium cobalt nanowire structure, comprising:
a substrate; and
a single-crystalline nanowire of claim 1,
wherein a long axis of the single-crystalline nanowire has a vertical alignment with respect to a surface of the substrate.

10. The germanium cobalt nanowire structure of claim 9, wherein the substrate is a flexible substrate.

11. The germanium cobalt nanowire structure of claim 9, wherein the substrate comprises a highly ordered pyrolytic graphite (HOPG) substrate, a graphene layer, a laminated graphene layer or a laminated substrate of them.

12. (canceled)

13. The germanium cobalt nanowire structure of claim 9, wherein a ratio calculated by dividing a length of the long axis by a diameter of a short axis in the single-crystalline nanowire is 5 to 200.

14. The germanium cobalt nanowire structure of claim 10, wherein the single-crystalline nanowire is an emitter of the electric emission display and the structure is provided in a cathode of the electric emission display.

15. (canceled)

16. A fabrication method of the germanium cobalt single-crystalline nanowire, wherein a heat-treatment on a first precursor containing halo-cobalt located on a upstream zone of a furnace, a second precursor containing germanium (Ge) located on a downstream zone of the furnace, and a substrate located on the downstream zone of the furnace are performed in an inert gas environment so that a single-crystalline CoₓGe₁₋ₓ nanowire having x of at least 0.01 to less than 0.99 is formed on the substrate.

17. The fabrication method of the germanium cobalt single-crystalline nanowire of claim 16, wherein the second precursor further contains carbon.

18. The fabrication method of the germanium cobalt single-crystalline nanowire of claim 17, wherein a ratio of germanium to cobalt composing the germanium cobalt single-crystalline nanowire is controlled by controlling a mixing ratio of germanium to carbon contained in the second precursor.

19. The fabrication method of the germanium cobalt single-crystalline nanowire of claim 18, wherein a mass ratio of germanium to carbon contained in the second precursor is 10:1 to 1:20.

20. The fabrication method of the germanium cobalt single-crystalline nanowire of claim 16, wherein a mass ratio of germanium to carbon contained in the second precursor is 0.8:1 to 1:0.8 and the nanowire is Co₅Ge₇.

21. (canceled)

22. The fabrication method of the germanium cobalt single-crystalline nanowire of claim 16, wherein the second precursor is located in a bottom part of the substrate.

23. The fabrication method of the germanium cobalt single-crystalline nanowire of claim 16, wherein the substrate comprises a highly ordered pyrolytic graphite (HOPG) substrate, a graphene layer, a laminated graphene layer or a laminated substrate of them.

24. The fabrication method of the germanium cobalt single-crystalline nanowire of claim 23, wherein the nanowire has a vertical alignment to a surface of the substrate.

25. The fabrication method of the germanium cobalt single-crystalline nanowire of claim 16, wherein the upstream zone of the furnace is maintained at a temperature of 500° C. to 800° C., the downstream zone of the furnace is maintained at a temperature of 600° C. to 1000° C. and the inert gas flows from the upstream zone to the downstream zone in the furnace and a flow rate of the inert as is 100 to 300 sccm.

26. (canceled)
